(19) United States
(12) Patent Application Publication
(10) Pub. No.: US 2009/0101207 A1
(43) Pub. Date: Apr. 23, 2009

(54) HERMETIC RECEIVER PACKAGE

(75) Inventors: Michael Milbourne, El Granada, CA (US); Harold Ackler, Sunnyvale, CA (US)

Correspondence Address: Heather Mueller;The Mueller Law Office, P.C., 12951 Harwick Lane, San Diego, CA, 92130, US

(73) Assignee: SolFocus, Inc., Mountain View, CA (US)

(21) Appl. No.: 12/032,696

(22) Filed: Feb. 18, 2008

Related U.S. Application Data
(60) Provisional application No. 60/980,773, filed on Oct. 17, 2007.

(51) Int. Cl. H01L 31/0232; H01L 31/18

(52) U.S. Cl. 136/259; 29/592.1

(57) ABSTRACT

The present invention is a hermetic receiver package for improving reliability of optical components within a solar concentrator system. The hermetic receiver package includes a non-imaging concentrator and a solar cell sealed within a shell structure to provide protection from environmental degradation. The non-imaging concentrator and solar cell are guarded from degradation caused by the outside environment as well as by sources within the solar concentrator system. Features are incorporated into the non-imaging concentrator and shell which allow the hermetic receiver package to be manufactured in a cost-effective manner.

### RELATED APPLICATIONS

This application claims priority to U.S. Provisional Patent Application Ser. No. 60/980,773 filed on Oct. 17, 2007 entitled “Hermetic Receiver Package,” which is hereby incorporated by reference as if set forth in full in this application for all purposes.

### BACKGROUND OF THE INVENTION

Solar concentrators are solar energy generators which increase the efficiency of converting solar energy into DC electricity. Solar concentrators known in the art utilize, for example, parabolic mirrors and Fresnel lenses for focusing incoming solar energy, and heliostats for tracking the sun's movements in order to maximize light exposure. Another type of solar concentrator, disclosed in U.S. Patent Publication No. 2006/0266408, entitled “Concentrator Solar Photovoltaic Array with Compact Tailored Imaging Power Units,” utilizes a front panel for allowing solar energy to enter the assembly, with a primary mirror and a secondary mirror to reflect and focus solar energy through a non-imaging concentrator onto a solar cell. The surface area of the solar cell in such a concentrator system is much smaller than what is required for non-concentrating systems, for example less than 1% of the entry window surface area. Such a system has a high efficiency in converting solar energy to electricity due to the focused intensity of sunlight, and also reduces cost due to the decreased surface area of costly photovoltaic cells.

A similar type of solar concentrator is disclosed in U.S. Patent Publication No. 2006/0207650, entitled “Multi-Junction Solar Cells with an Aplanatic Imaging System and Coupled Non-Imaging Light Concentrator.” The solar concentrator design disclosed in this application uses a solid optic, out of which a primary mirror is formed on its bottom surface and a secondary mirror is formed in its upper surface. Solar radiation enters the upper surface of the solid optic, reflects from the primary mirror surface to the secondary mirror surface, and then enters a non-imaging concentrator which outputs the light onto a photovoltaic solar cell.

In these and other solar concentrators, it is important that components be protected from the harsh conditions of the outside environment. Dirt, debris, airborne chemicals, moisture, and the like can hinder the optical performance of the various components as well as cause degradation of materials over time. To address this problem, some solar energy systems have provided environmental protection by encasing the entire solar concentrator unit in a sealed enclosure. For instance, systems have utilized tubular enclosures with sealed end caps to protect a solar concentrator unit, or have utilized seals in assembling the outer components of a solar energy system together. Other approaches specifically address protecting the photovoltaic solar cells, including methods such as encapsulating solar cells with protective adhesives or coatings, utilizing glass coverings, or containing the solar cells in sealed cases.

While these approaches meet the needs of certain configurations of solar concentrator systems, the need for new improvements to protect components from environmental influences may arise as solar concentrator designs continue to develop. Continuing improvement in environmental protection can also increase the performance and reliability of current solar concentrators. Furthermore, providing environmental protection in ways which are cost-effective and easy to manufacture can provide additional advantage over existing methods.

### SUMMARY OF THE INVENTION

The present invention is a hermetic receiver package for improving reliability of optical components within a solar concentrator system. The hermetic receiver package includes a non-imaging concentrator and a solar cell sealed within a shell structure to provide protection from environmental degradation. The non-imaging concentrator and solar cell are guarded from degradation caused by the outside environment as well as by sources within the solar concentrator system. In one embodiment, the shell may be manufactured in a cost-effective manner from standard sheet glass. In other embodiments, manufacturing features facilitate spacing and alignment between the non-imaging concentrator and shell during assembly of the hermetic receiver package.

### BRIEF DESCRIPTION OF THE DRAWINGS

FIG. 1 is a cross-sectional view of an exemplary solar concentrator unit;

FIG. 2 provides an exploded perspective view of the non-imaging concentrator and solar cell from FIG. 1;

FIG. 3 depicts an exploded perspective view of an exemplary hermetic receiver package of the present invention;

FIG. 4 illustrates a cross-sectional view of the hermetic receiver package of FIG. 3;

FIG. 5 shows a cross-sectional view of another exemplary hermetic receiver package of the present invention;

FIG. 6 is an exploded perspective view of yet another embodiment of the present invention;

FIG. 7 is a cross-sectional view of the hermetic receiver package of FIG. 6; and

FIG. 8 is a flowchart of an exemplary process for manufacturing a hermetic receiver package.

### DETAILED DESCRIPTION OF THE EMBODIMENTS

Reference now will be made in detail to embodiments of the disclosed invention, one or more examples of which are illustrated in the accompanying drawings.

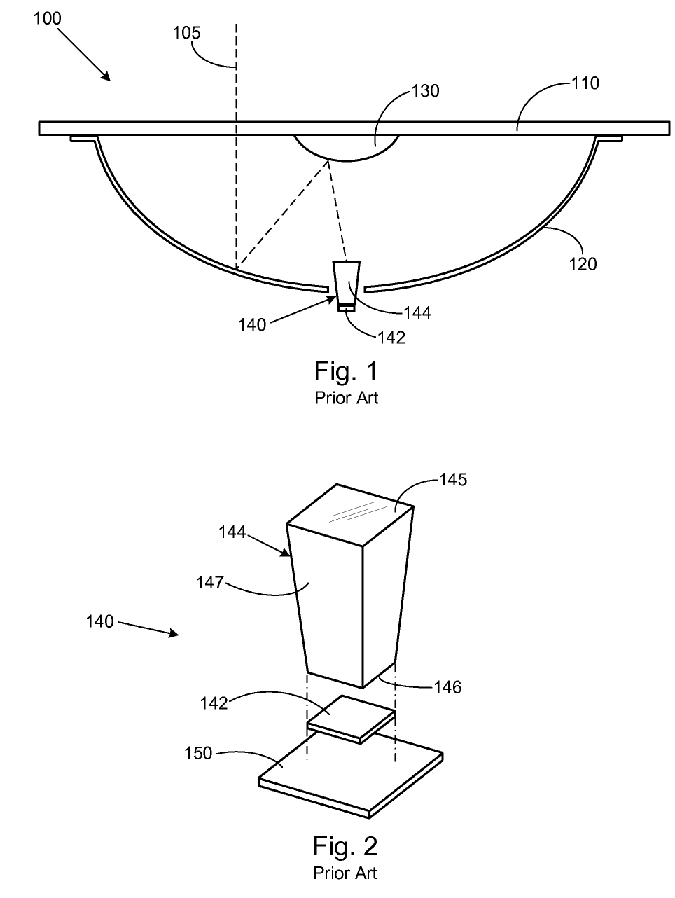

FIG. 1 depicts a cross-sectional view of an exemplary solar concentrator unit 100 as disclosed in U.S. Patent Publication No. 2006/0266408, entitled “Concentrator Solar Photovoltaic Array with Compact Tailored Imaging Power Units.” Solar radiation 105, represented by dashed lines, enters solar concentrator unit 100 through a front panel 110, reflects off a primary mirror 120 and secondary mirror 130, and then enters an optical receiver 140. Optical receiver 140 includes a photovoltaic solar cell 142, also referred to as a “die,” where solar radiation 105 is converted to electricity, and may also include a non-imaging concentrator 144. Non-imaging concentrator 144 serves as a conduit to deliver solar radiation 105 to solar cell 142. Non-imaging concentrator 144 provides the potential to increase the acceptance angle of solar concentrator unit 100, and allows solar cell 142 to be located behind primary mirror 120 where heat sinking of solar cell 142 may be added.

A close-up drawing of optical receiver 140, including non-imaging concentrator 144 and solar cell 142, is provided in the exploded perspective view of FIG. 2. A base 150 is also depicted in FIG. 2 for mounting solar cell 142. Non-imaging concentrator 144 has an entrance aperture 145, an exit aperture 146, and side faces 147, and delivers light by, for example, total internal reflection. In one embodiment, non-imaging concentrator 144 may be a truncated pyramid having a height in the range of 25-35 millimeters and an entrance aperture 145 shaped as a square of approximately 15-20 millimeters in width. Note that while non-imaging concentrator 144 is depicted in FIG. 2 as a truncated pyramid, it may take other forms such as a hexagonal pyramid, a truncated cone, a truncated paraboloid, or a rectangular or cylindrical prism. Furthermore, while entrance aperture 145 is shown to be a flat surface, it may take other forms such as being convex or angled while still remaining within the scope of the present invention. Solar cell 142 is positioned underneath non-imaging concentrator 144 to receive light through exit aperture 146. Base 150 represents a circuit board to which photovoltaic solar cell 142 delivers its converted energy. Base 150 may be, for example, a ceramic package to which solar cell 142 is wire-bonded.

Solar radiation may be delivered through the non-imaging concentrator 144 of FIG. 2 by total internal reflection. That is, light passing through non-imaging concentrator 144 impacts side faces 147 at such an angle that the light reflects internally within non-imaging concentrator 144 rather than refracting and passing through side faces 147. The critical angle required for total internal reflection is determined by the difference in refraction indices at the interface being considered. For a non-imaging concentrator 144 made of, for example, glass, the total internal reflection properties would be determined by the refraction indices of glass and the surrounding air. However, accumulation of contaminants on side faces 147 can alter the total internal reflection properties of non-imaging concentrator 144, causing transmission losses for the solar concentrator system. Thus, the performance and reliability of a solar concentrator system which uses a total internal reflection member such as non-imaging concentrator 144 is improved by guarding not only the solar cell 142 against environmental degradation, but also the side faces 147 of non-imaging concentrator 144. Furthermore, it is advantageous to provide protection against outside environmental influences as well as from internal sources of contamination. Contaminants originated from the outside environment include moisture, particulates, and airborne chemicals, while those generated internally from a solar concentrator unit may include outgassing of nearby adhesives or coating materials.

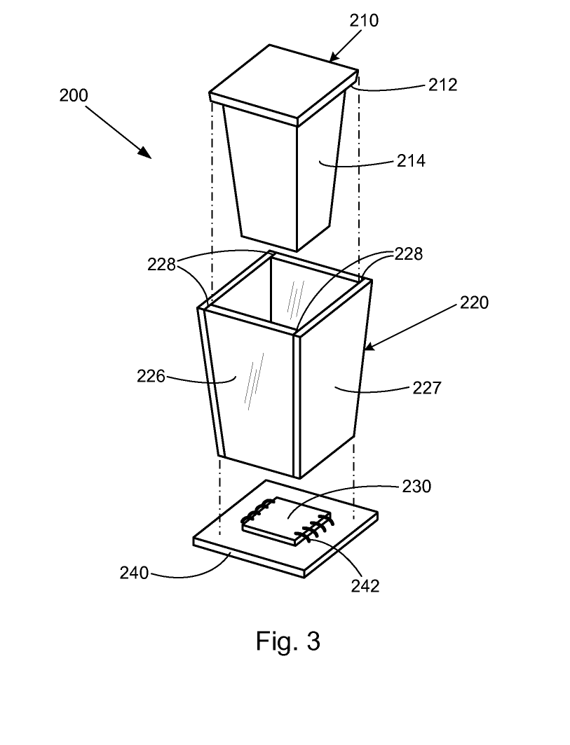

To provide such protection, an exemplary hermetic receiver package 200 of the present invention is depicted in the exploded perspective view of FIG. 3. Receiver package 200 includes a non-imaging concentrator 210, a shell 220, and a solar cell 230 mounted to a base 240. Solar cell 230 may be mounted to base 240 by, for example, having a bottom contact (not shown) soldered or die-attached with conductive epoxy and having top contacts coupled by wire bonds 242, metal wings, or other conductive paths. In this embodiment of FIG. 3, non-imaging concentrator 210 includes wings 212 and side faces 214, while shell 220 includes side walls 226 and end walls 227. When hermetic receiver package 200 is assembled, shell 220 surrounds and is joined to non-imaging concentrator 210 and to base 240, thus hermetically sealing solar cell 230 and side faces 214 of non-imaging concentrator 210 from environmental influences. In the depicted embodiment, shell 220 is formed from trapezoidal side walls 226 and end walls 227 to enclose the truncated pyramid non-imaging concentrator 210. Side walls 226 and end walls 227 may be, for example, cut into shape from a sheet of glass and then fritted together by butt joints 228 at the ends of side walls 226. The ability to utilize standard glass materials and joining methods allows shell 220 to be manufactured in a cost-effective manner.

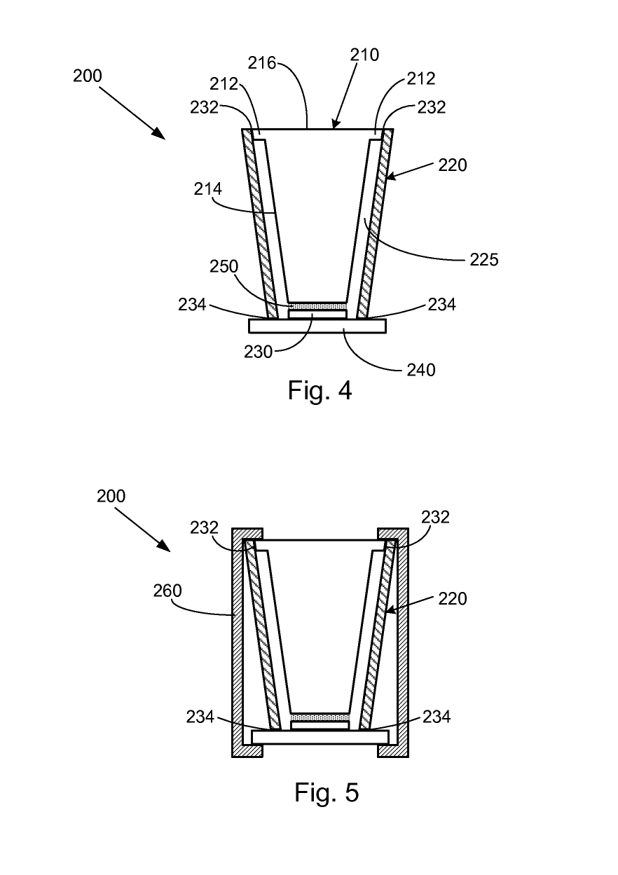

Further details of the exemplary receiver package 200 of FIG. 3 are shown in the assembled cross-sectional view of FIG. 4. Non-imaging concentrator 210 is seated inside shell 220 and sealed to shell 220 at joints 232, for example by fritting with a lower temperature frit than that which was used to fabricate shell 220 (butt joints 228 of FIG. 3). The combination of non-imaging concentrator 210 joined to shell 220 forms a stable geometry which improves the robustness of the assembly. Protrusions in the form of wings 212 near entrance aperture 216 of non-imaging concentrator 210 create a spacing 225 between shell 220 and the lateral surfaces embodied by side faces 214. This spacing 225 preserves the air gap required around side faces 214 for achieving total internal reflection, and should have a width of at least one wavelength of light, determined by the longest wavelength light collected, away from the side faces 214. Spacing 225 may have a width of, for example, 1-2 millimeters to accommodate wire bonds 242 of FIG. 3. Wings 212 facilitate alignment of non-imaging concentrator 210 within shell 220 with minimal or no manufacturing fixturing. In the embodiment shown in FIG. 4, wings 212 are formed integrally with non-imaging concentrator 210. For a non-imaging concentrator 210 made of glass, wings 212 may be formed, for example, by grinding and polishing, or by molding. Wings 212 need not be rectilinear in cross-section, nor do they need to be integral to non-imaging concentrator. For instance, the cross-section of wings 212 may be rounded, with frit or another suitable bonding substance filling any gaps as necessary to form a hermetic seal. In other embodiments, wings 212 may be protrusions integral to shell 220 instead of to non-imaging concentrator 210, or may be separate spacing rods placed between non-imaging concentrator 210 and shell 220. In yet another embodiment, the base 240 may include protrusions integral to its surface to assist in achieving the spacing 225. Note that while the spacing 225 is depicted as being symmetrical around non-imaging concentrator 210, non-uniform spacing is also possible. For example, solar cell 230 may be mounted with wire bonds 242 located on only one of its four sides. In such a situation, spacing 225 may be uniform around three sides of solar cell 230 but have a wider spacing on the fourth side to accommodate wire bonds 242. The geometry of shell 220 may also be altered accordingly to accommodate the asymmetric positioning of solar cell 230.

Continuing with FIG. 4, a coupling material 250 of suitable optical index, such as an optical encapsulant or sol-gel material, may be included between solar cell 230 and non-imaging concentrator 210. Alternatively, solar cell 230 may be placed directly in contact with non-imaging concentrator 210, or the space occupied by coupling material 250 may be left as an air gap depending on the optical properties of non-imaging concentrator 210. Shell 220 is sealed to base 240 at joints 234, such as by low temperature fritting. The spacing 225 is evacuated to remove moisture and chemicals, such as gases produced during curing of coupling material 250, from within receiver package 200 prior to completing the seal around the entire perimeter of joints 234. The entire receiver package 200 may be assembled in a vacuum oven during a production process.

To provide further stability, the receiver package 200 may be put under mild compression as shown in the exemplary embodiment of FIG. 5. This has the effect of post-tensioning the shell 220 to keep the fritted joints 234 in compression, thus helping joints 234 to resist detachment arising from forces or bending moments caused by handling, jarring, or by gravity. In the depicted embodiment, compression may be applied by a bracket 260 spanning the height of receiver package 200. Bracket 260 may be made of a material having a coefficient of thermal expansion matching that of shell 220. In other embodiments, elements such as a spring clip or a face plate coupled to surrounding components of the solar concentrator system may be used to apply compression.

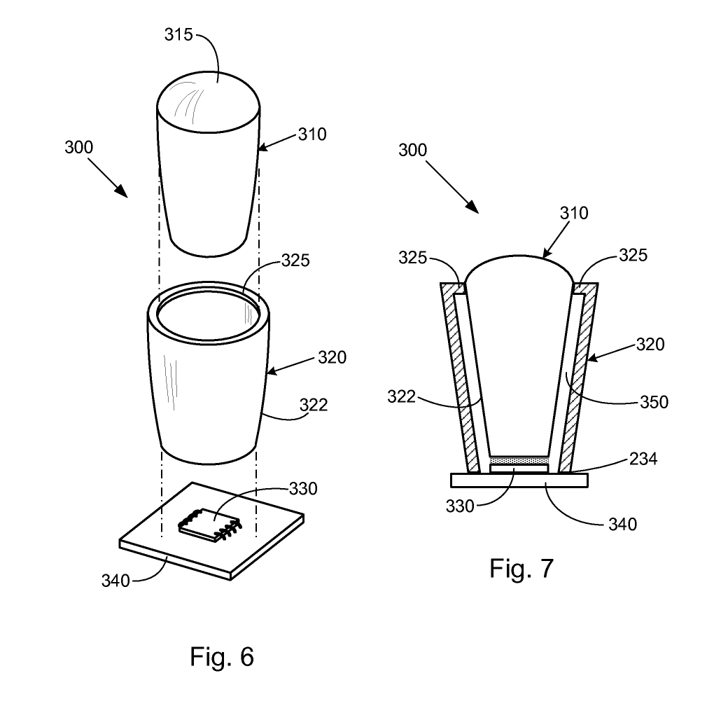

FIGS. 6 and 7 illustrate yet another embodiment of the present invention. A hermetic receiver package 300 incorporates a non-imaging concentrator 310 with a circular cross-section, an approximately cylindrical shell 320, a solar cell 330 and a base 340. Turning to FIG. 6, non-imaging concentrator 310 also includes an entrance aperture 315 which is convex rather than flat as previously shown in the embodiment of FIG. 3. Cylindrical shell 320 may be formed from, for example, a glass tube being blown out to or drawn down to the appropriate size and profile, and then cut to length. Turning to the embodiment depicted in FIG. 7, a protrusion for setting the spacing 350 between cylindrical shell 320 and the lateral surface 322 of non-imaging concentrator 310 takes the form of a lip 325 integral to cylindrical shell 320, rather than being integral to the non-imaging concentrator 210 as in FIGS. 3 and 4.

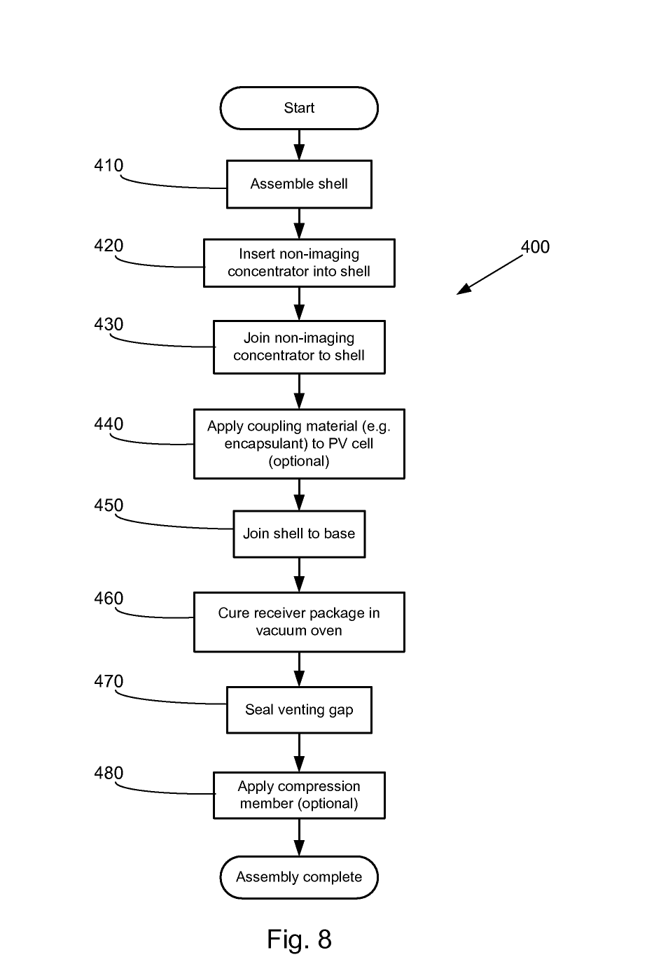

Now turning to FIG. 8, an exemplary process for manufacturing a hermetic receiver package of the present invention is illustrated. Flowchart 400 of FIG. 8 begins with assembling a shell in step 410, such as by joining together the side walls 226 and end walls 227 of FIG. 3 with a high temperature frit. Next, in step 420 a non-imaging concentrator is inserted into the shell, insuring that a spacing between non-imaging concentrator and shell is achieved. If the protrusions used to set the spacing, such as wings 212 of FIG. 4 or lip 325 of FIG. 7, are not integral to either the non-imaging concentrator or shell, then a similar component such as spacing rods may be added during step 420. The non-imaging concentrator is joined to the shell in step 430, such as by a second fritting operation which is performed at a lower temperature than the softening point of the first frit used to assemble the shell in step 410.

Prior to mounting the shell and non-imaging concentrator onto a base, a coupling material such as an optical encapsulant or an adhesive may be applied to the solar cell in step 440. The coupling material may be applied either the exit aperture of the non-imaging concentrator or to the solar cell. Note that the solar cell would typically be supplied as a sub-assembly already mounted onto a base, or electrical board. The coupling material may be desirable for enhancing light transmission from the non-imaging concentrator to the solar cell, or for providing additional protective sealing of the solar cell. The choice of coupling material should have minimal outgassing within the operational temperatures of the solar concentrator system.

In step 450 of FIG. 8, the shell and base are joined together, thus enclosing the non-imaging concentrator and solar cell inside. To perform step 450, a frit, adhesive, or other bonding substance is applied around the bottom edges of the shell, leaving a gap in, for example, one of the corners of the shell. Alternatively, a venting gap may be located in, for example, the joint between the non-imaging concentrator and the shell, or may take the form of a through-hole in the base for gases to vent out of the bottom of the receiver package. The receiver package is placed in a vacuum oven in step 460 to cure the bonding substance between the base and the shell and to vent gases from within the receiver package assembly. Once cured, the venting gap is sealed, as indicated in step 470, in a vacuum or low pressure inert atmosphere to prevent unwanted substances such as moisture or airborne chemicals from re-entering the hermetic receiver package. Lastly, in step 480 a compression member may optionally be applied to the hermetic receiver package.

Although embodiments of the invention have been discussed primarily with respect to specific embodiments thereof, other variations are possible. For instance, while the hermetic receiver package of the present invention has been described in relation to a solar concentrator as exemplified in FIG. 1, the hermetic receiver package may similarly be applied to other types of light delivery systems which involve a total internal reflecting or similar element, such as parabolic and Fresnel-based concentrator systems. In another modification, other optical components such as refractive lenses may be enclosed within the hermetic receiver package in addition to the non-imaging concentrator and photovoltaic cell described in this specification. Furthermore, although the manufacturing process and flowchart described herein describes one possible sequence of steps for assembling the hermetic receiver package of the present invention, other variations are possible. For instance, the non-imaging concentrator may be joined to the shell after the shell has been secured to the base instead of prior to securing the shell to the base. Steps can be added to, taken from, or modified from the steps in this specification without deviating from the scope of the invention.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention, which is more particularly set forth in the appended claims. Furthermore, those of ordinary skill in the art will appreciate that the foregoing description is by way of example only, and is not intended to limit the invention. Thus, it is intended that the present subject matter covers such modifications and variations as come within the scope of the appended claims and their equivalents.

What is claimed is:

1. A hermetic receiver package, comprising:
a non-imaging concentrator having an entrance aperture, an exit aperture and a lateral surface;
a solar cell positioned to receive light transmitted from said exit aperture of said non-imaging concentrator;
a shell surrounding said non-imaging concentrator and said solar cell, said shell having a top end and a bottom end, wherein said top end of said shell is coupled to said non-imaging concentrator near said entrance aperture, and wherein said shell is spaced away from said lateral surface of said non-imaging concentrator; and
a base coupled to said shell near said bottom end of said shell.

2. The hermetic receiver package of claim 1, wherein said non-imaging concentrator is configured with integral protrusions near said entrance aperture to cause said shell to be spaced away from said lateral surface of said non-imaging concentrator.

3. The hermetic receiver package of claim 1, wherein said non-imaging concentrator is a truncated pyramid configured for total internal reflection.

4. The hermetic receiver package of claim 1, wherein said non-imaging concentrator is made of glass, wherein said shell is made of glass, and wherein said shell is coupled to said non-imaging concentrator by fritting.

5. The hermetic receiver package of claim 1, further comprising a coupling material between said solar cell and said exit aperture of said non-imaging concentrator.

6. The hermetic receiver package of claim 1, wherein said shell is spaced away from said lateral surface of said non-imaging concentrator by a distance of at least one wavelength of light.

7. The hermetic receiver package of claim 1, further comprising a vacuum environment enclosed by said shell.

8. The hermetic receiver package of claim 1, wherein said base comprises a circuit board, and wherein said solar cell is electrically connected to said base.

9. The hermetic receiver package of claim 1, wherein said base is coupled to said shell by fritting.

10. The hermetic receiver package of claim 1, further comprising a compression member for applying compression from said top end of said shell to said bottom end of said shell.

11. A method of manufacturing a hermetic receiver package, said hermetic receiver package comprising a non-imaging concentrator having an entrance aperture, an exit aperture and a lateral surface, a shell having a top end and a bottom end, and a solar cell coupled to a base, said method comprising the steps of:
attaching said top end of said shell to said non-imaging concentrator near said entrance aperture of said non-imaging concentrator, positioning said shell around said non-imaging concentrator and spaced away from said lateral surface of said non-imaging concentrator;
securing said base to said shell near said bottom end of said shell; and
hermetically sealing said shell to said non-imaging concentrator and to said base.

12. The method of manufacturing a hermetic receiver package of claim 11, wherein said step of hermetically sealing comprises applying a vacuum.

13. The method of manufacturing a hermetic receiver package of claim 11, wherein said step of attaching comprises fritting.

14. The method of manufacturing a hermetic receiver package of claim 11, wherein said shell is constructed of glass walls.

15. The method of manufacturing a hermetic receiver package of claim 14, wherein said glass walls are trapezoidal in shape and said non-imaging concentrator is a truncated pyramid.

16. The method of manufacturing a hermetic receiver package of claim 14, further comprising the step of assembling said glass walls by fritting at a first temperature, and wherein said step of attaching comprises fritting at a second temperature which is lower than said first temperature.

17. The method of manufacturing a hermetic receiver package of claim 11, further comprising the step of encapsulating said photovoltaic cell.

18. The method of manufacturing a hermetic receiver package of claim 11, wherein said step of securing comprises fritting.

19. The method of manufacturing a hermetic receiver package of claim 11, wherein said non-imaging concentrator comprises integral protrusions, and wherein said integral protrusions are used to space said shell away from said non-imaging concentrator during said step of positioning.

20. The method of manufacturing a hermetic receiver package of claim 11, wherein said shell is spaced away from said non-imaging concentrator by a distance of at least one wavelength of light.
